(19) United States
(12) Patent Application Publication
(10) Pub. No.: US 2008/0211018 A1
(43) Pub. Date: Sep. 4, 2008

(54) SEMICONDUCTOR DEVICE AND METHOD OF MANUFACTURING THE SAME

(75) Inventor: Yoshikazu MORIWAKI, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/965,122

(22) Filed: Dec. 27, 2007

(30) Foreign Application Priority Data
Dec. 28, 2006 (JP) 2006-355440

(51) Int. Cl. H01L 27/088; H01L 21/8234

(52) U.S. Cl. 257/333; 438/270; 257/E27.06; 257/E21.621

(57) ABSTRACT

This semiconductor device includes a trench gate transistor including a groove formed on a semiconductor, a gate electrode formed in the groove via a gate insulating film, and a source and a drain disposed near the gate electrode on the semiconductor substrate via the gate insulating film. The gate electrode extends from an inner side of the groove to an outer side of the groove. The gate electrode has a misalignment portion in a width direction from the inner side of the groove to the outer side of the groove. The misalignment portion of the gate electrode is formed at a side higher than an opening edge of the groove. A height from the opening edge of the groove to the misalignment portion is larger than a thickness of the gate insulating film.

### BACKGROUND OF THE INVENTION

Priority is claimed on Japanese Patent Application No. 2006-355440, filed Dec. 28, 2006, the contents of which are incorporated herein by reference.

1. Field of the Invention

The present invention relates to a semiconductor device having a trench gate structure and a method of manufacturing the same.

2. Description of the Related Art

Memory cells, such as DRAM (Dynamic Random Access Memory) and the like, each including select transistors and capacitors, have reduced dimensions of transistors and a remarkable short channel effect of transistors due to such reduction of dimensions as semiconductor devices grow smaller and smaller. For high capacity DRAMs, although a channel length of a transfer gate transistor may be reduced with reduction of memory cell dimensions, it may deteriorate retention and write characteristics of DRAM memory cells as an S value of the transfer gate transistor increases.

As one of measures against the short channel of transistors or for the purpose of improving refresh characteristics of DRAMs, trench gate transistors having a 3-dimensional channel structure have been developed. A trench gate transistor refers to a transistor in which a groove is formed in a semiconductor substrate and a channel length is extended by effectively using a 3-dimensional groove interface as a channel. By employing such a trench gate transistor (also called RCAT (Recess Channel Access Transistor)) structure, it is possible to take measures against short channel of transistors and improve refresh characteristics of DRAMs. For example, since the trench gate transistor suture can make the channel length long, it is possible to tin a channel dose and realize a refresh enhancement effect due to PN junction electric field relaxation of source and drain regions.

FIGS. 15 to 18 show an example of a method of manufacturing this kind of trench gate transistor structure.

As shown in FIG. 15, a device isolation insulating film 103 is formed to partition device forming regions on a Si substrate 102 by a STI (Shallow Trench Isolation) method, and then, required number of trenches (grooves) 104 are formed in a portion to be a gate electrode region using a photolithography method and a dry etching method.

Next as shown in FIG. 16, a surface of the Si substrate 102 is oxidized by a thermal oxidation method to form a gate insulating film 106 having thickness of 3 nm to 10 nm. After for the gate insulting film 106, as shown in FIG. 17, a gate electrode layer 105 having thickness of 50 nm to 100 nm is formed by a CVD (Chemical Vapor Deposition) method, a WSi lower film having thickness of 5 nm to 10 nm is further formed by a CVD. Subsequently, a barrier layer of a tungsten nitride film (WNx film) having thickness of 10 nm or so is formed by a sputtering method, and a laminated film 107 having a 3-layer structure is further formed by forming a metal layer of a tungsten film having thickness of 5 nm or so. Subsequently, a SiN mask layer 108 having thickness of 140 nm or so is formed by a CVD method to obtain a laminated structure as shown in FIG. 17.

Next, a portion of the mask layer 103, a portion of the laminated film 107 and a portion of the gate electrode layer 105 are patterned by a photolithography method, and then are dry etched up to a surface of the gate electrode layer 105 through the laminated film 107 among the mask layer 108, the laminated film 107 and the gate electrode layer 105. Subsequently, a SiN coating insulating film 109 is thinly formed as a barrier layer of the WSi lower film, and the remainder of the gate electrode layer 105 is etched.

Through the above process, as shown in FIG. 18, it is possible to obtain a gate electrode 105C including a lower gate electrode 105A provided inside a groove 104 and an upper gate electrode 105B projected upward from the groove 104, and a gate electrode laminate 110 having a laminated structure of a laminate 107A and a mask insulating film 108A to extend the gate electrode 105C.

In the trench gate transistor structure shown in FIG. 18, if the gate electrode 105C is formed by the dry etching method, there may occur a misalignment between the upper gate electrode 105B and the lower gate electrode 105A, which may be caused by the photolithography method, with miniaturization of the transistor structure.

If a step 105D occurs between the lower gate electrode 105A and the upper gate electrode 105B due to such a misalignment, the step 105D contacting the gate insulating film 106 and extending nearest to the source and drain regions may increase a parasitic capacitance (overlap capacitance), which may result in increase of gate delay. In addition, since an electric field between the gate electrode 105C and the source and drain regions is concentrated on the step 105D, a GIDL (gate induced drain leakage) withstand voltage and reliability of the gate insulating film may be deteriorated.

In particular, when the trench gate resistor is applied to DRAMs, since a plurality of trench gate transistors are connected to word lines and bit lines, the gate delay with increase of parasitic capacitance is problematic.

Japanese Unexamined Patent Application, First Publication No. 2002-164537 (hereinafter referred to patent document) has been known as a prior technology document disclosing a technique of reducing the above-mentioned GIDL withstand voltage in the field of transistor technologies. This patent document discloses a structure including a gate insulating formed on a semiconductor substrate, a gate electrode formed on the gate insulating film and having a notch formed at an end below a side wall of the gate electrode, and an impurity diffusing layer formed in a source/drain region of the semiconductor substrate, a width of a lower surface of the gate electrode being formed to be narrower than a width of an upper surface of the gate electrode, and the gate insulating film at the notch portion being formed to be thicker than the gate insulating film below the center of the gate electrode.

Although the technique disclosed in the above patent document has been proposed to reduce the GIDL withstand voltage in the conventional transistor structure, this technique can not be simply applied to solve the above problem related to the GIDL withstand voltage in the above-mentioned trench gate transistor structure.

Accordingly, there is a need to solve the problems of increase of parasitic capacitance (overlap capacitance) occurring due to the misalignment, increase of the gate delay, and deterioration of the GIDL withstand voltage and reliability of the gate insulating film, which may be caused by the step 105D of the gate electrode 105 which is located nearest to the source/drain region and on which the electric field is concentrated.

In consideration of the above circumstances, an object of the present invention is to provide a semiconductor device which is capable of avoiding problems of increase of parasitic capacitance and gate delay, suppressing a GIDL withstand voltage from being lowered, and enhancing reliability of a gate insulating film in a trench gate transistor stricture, and a method of manufacturing the semiconductor device.

### SUMMARY OF THE INVENTION

(1) According to an aspect of the present invention, there is provided a semiconductor device including a trench gate transistor including a groove formed on a semiconductor, a gate electrode formed in the groove via a gate insulating film, and a source and a drain disposed near the gate electrode on the semiconductor substrate via the gate insulating film. The gate electrode extends from an inner side of the groove to an outer side of the groove. The gate electrode has a misalignment portion in a width direction from the inner side of the groove to the outer side of the groove. The misalignment portion of the gate electrode is formed at a side higher than an opening edge of the groove. And a height from the opening edge of the groove to the misalignment portion is larger than a thickness of the gate insulating film.
(2) Preferably, a portion from a side wall of the gate electrode located at the opening edge of the groove formed on the semiconductor substrate to the misalignment portion of the gate electrode is surrounded by an interlayer insulating film laminated on the semiconductor substrate.
(3) Preferably, the gate electrode is divided into a lower gate electrode and an upper gate electrode by the misalignment portion; and the top of the lower gate electrode extends upper than the opening edge of the groove and the gate electrode around the opening edge.
(4) Preferably, a conductor and a mask insulating film are formed on the upper gate electrode to extend the gate electrode; and the semiconductor device further includes a coating insulating film covering the mask insulating film, the conductor and the upper gate electrode.
(5) Preferably, a source electrode and a drain electrode are respectively formed in the source and the drain provided through the interlayer insulating film and the gate insulating film.
(6) According to another aspect of the present invention, there is provided a method of manufacturing a semiconductor device, including the steps of forming a device isolation insulating film on a semiconductor substrate; laminating a buffer insulating film on the semiconductor substrate on which the device isolation film is formed; forming a groove reaching the semiconductor substrate through the buffer insulating film; forming a gate insulating film by oxidizing the groove and the semiconductor substrate around tee groove by an oxidation method; for an electrode film on the semiconductor substrate on which the buffer insulating film and the groove are formed, such that the electrode film fills up the internal of the groove and is deposited over the internal of the groove; forming a conductive film and a mask layer on the electrode film; patterning the mask layer; forming an gate electrode having a misalignment portion in a width direction from an inner side of the groove to an outer side of the groove by machining the conductive film and the electrode film via the mask layer, and forming a source and a drain on the semiconductor adjacent to the gate electrode by ion implantation.
(7) Preferably, the method further includes the steps of: after forming the gate electrode having the misalignment portion, exposing the gate insulating film around the gate electrode by removing the buffer insulating film on the semiconductor substrate; and, after exposing the gate insulating film, forming the source and the drain on the semiconductor substrate adjacent to the gate electrode by the ion implantation.
(8) Preferably, the method further includes the steps of: after forming the source and the drain, forming an interlayer insulating film to surround the gate electrode, the conductive film and the mask layer; and forming a source electrode and a drain electrode connecting to the source and the drain, respectively, through the interlayer insulating film.

As described above, with the structure of the present invention, even when the gate electrode is formed in misalignment due to photolithography with miniaturization of a trench gate transistor structure, since the misalignment portion of the gate electrode is upper than the opening edge of the groove and is isolated from and disposed above the gate insulating film, the misalignment portion of the gate electrode will not be disposed adjacent to the source or the drain via the gate insulating film. Accordingly, there occurs no increase of parasitic capacitance due to an overlap of the gate electrode and the source/drain. In addition, since the misalignment portion of the gate electrode is isolated from and disposed above the gate insulating film in the opening edge of the groove, the misalignment portion is sufficiently isolated from the source/drain, and accordingly, an electric field is hardly concentrated on an edge of the misalignment portion. Accordingly, it is possible to prevent a GIDL wit d voltage and reliability of the gate insulating film from being deteriorated in the transistor structure.

As can be seen from the above description, the present invention provides a semiconductor device with small parasitic capacitance and no gate delay even in misalignment of the gate electrode, and further, a semiconductor device without concentration of an electric field on the edge of the misalignment portion of the gate electrode and without deterioration of the GIDL withstand voltage.

When the a portion from the side wall of the gate electrode projected in an outer side of the groove to the misalignment portion of the gate electrode is surrounded by the interlayer insulating film, the interlayer insulating film and the gate insulating film are interposed between the misalignment portion and the source/drain, and accordingly, an electric field is hardly concentrated on the misalignment portion of the gate electrode, and it is possible to prevent a GIDL withstand voltage from being deteriorated.

When a miniaturized trench gate transistor is manufactured by forming the buffer insulating film on the semiconductor substrate on which the device isolation insulating film is formed, forming the groove; forming the gate insulating film in and around the groove, forming the electrode film, the conductive film and the mask layer on the groove and the buffer insulating film, and forming the gate electrode projecting from the inner side to the outer side of the groove by the photolithography method, even if the gate electrode has an misalignment portion due to overlap precision of the photolithography method, since the misalignment portion of the gate electrode is sufficiently isolated from the semiconductor substrate and hence the source/drain by the thickness of the buffer insulating film, an electric field is hardly concentrated on the edge of the misalignment portion. Accordingly, it is possible to provide a semiconductor device having a trench structure, which is capable of preventing a GIDL withstand voltage and reliability of a gate insulating film from being deteriorated in a trench gate transistor.

### BRIEF DESCRIPTION OF THE DRAWINGS

FIG. 1 is a conceptual view showing a section structure of a semiconductor device according to a first embodiment of the present invention.

FIG. 2 is a conceptual sectional view for explaining a method of manufacturing the semiconductor device, showing a state where a trench isolation insulating film and a buffer insulating film are formed on a semiconductor substrate.

FIG. 3 is a conceptual sectional view for explaining a method of manufacturing the semiconductor device, showing a sate where a groove and a gate insulating film are formed.

FIG: 4 is a conceptual sectional view for explaining a method of manufacturing the semiconductor device, showing a state where a gate electrode film, a laminated film and a mask insulating layer are formed on a semiconductor substrate.

FIG. 5 is a conceptual sectional view for explaining a method of manufacturing the semiconductor device, showing a state where a gate electrode film is etched up to a buffer insulating film.

FIG. 6 is a conceptual sectional view for explaining a method of manufacturing the semiconductor device, showing a state where a buffer insulating film is removed.

FIG. 7 is a conceptual sectional view for explaining a method of manufacturing the semiconductor device, showing a state where ions are injected into a semiconductor substrate around a groove.

FIG. 8 is a conceptual sectional view for explaining a method of manufacturing the semiconductor device, showing a state where an interlayer insulating film is formed around a gate electrode, a contact plug is additionally formed, and a metal wire is formed.

FIG. 9 is a sectional view of a semiconductor substrate having a gate electrode laminate formed thereon for explaining a method of manufacturing a contact plug by a SAC method.

FIG. 10 is a sectional view for explaining a method of manufacturing a contact plug by a SAC method, showing a state where a gate side wall protection film is formed on a semiconductor substrate hang a gate electrode laminate formed thereon.

FIG. 11 is a sectional view for explaining a method of manufacturing a contact plug by a SAC method, showing a state where an interlayer insulating film is formed on a gate side wall protection film.

FIG. 12 is a sectional view for explaining a method of manufacturing a contact plug by a SAC method, showing a state where a contact hole passing through an interlayer insulating film is formed.

FIG. 13 is a sectional view for explaining a method of manufacturing a contact plug by a SAC method, showing a state where a side wall film is formed in a contact hole and on an interlayer insulating film.

FIG. 14 is a sectional view for explaining a method of manufacturing a contact plug by a SAC method, showing a state where a side wall film and a lower portion of a contact hole on an interlayer insulating film are removed to leave a side wall film in the contact hole.

FIG. 15 is a conceptual sectional view for explaining a method of manufacturing a conventional semiconductor device, showing a state where a groove is formed on a semiconductor substrate.

FIG. 16 is a conceptual sectional view for explaining a method of manufacturing a conventional semiconductor device, showing a state where a gate insulating film is formed around a groove of a semiconductor substrate.

FIG. 17 is a conceptual sectional view for explaining a method of manufacturing a conventional semiconductor device, showing a state where a gate electrode layer, a laminated film and a mask insulating layer are formed on a semiconductor substrate.

FIG. 18 is a conceptual sectional view showing an example of a conventional semiconductor device.

### DETAILED DESCRIPTION OF THE INVENTION

Hereinafter, a semiconductor device according to an exemplary embodiment of the present invention will be described wit reference to the accompanying drawings; however, it should be understood that the present invention is not limited only to this exemplary embodiment.

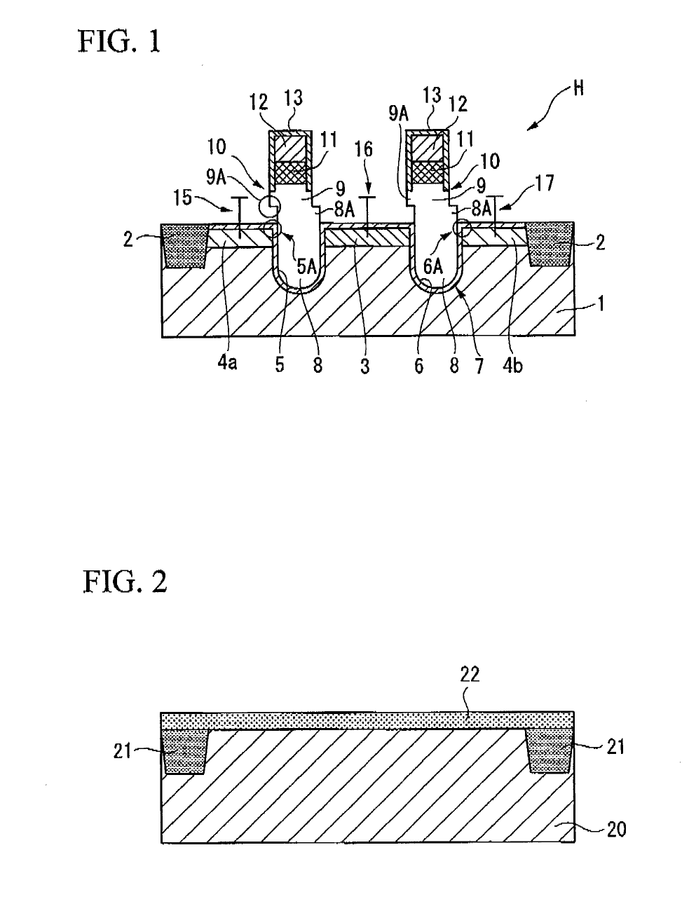

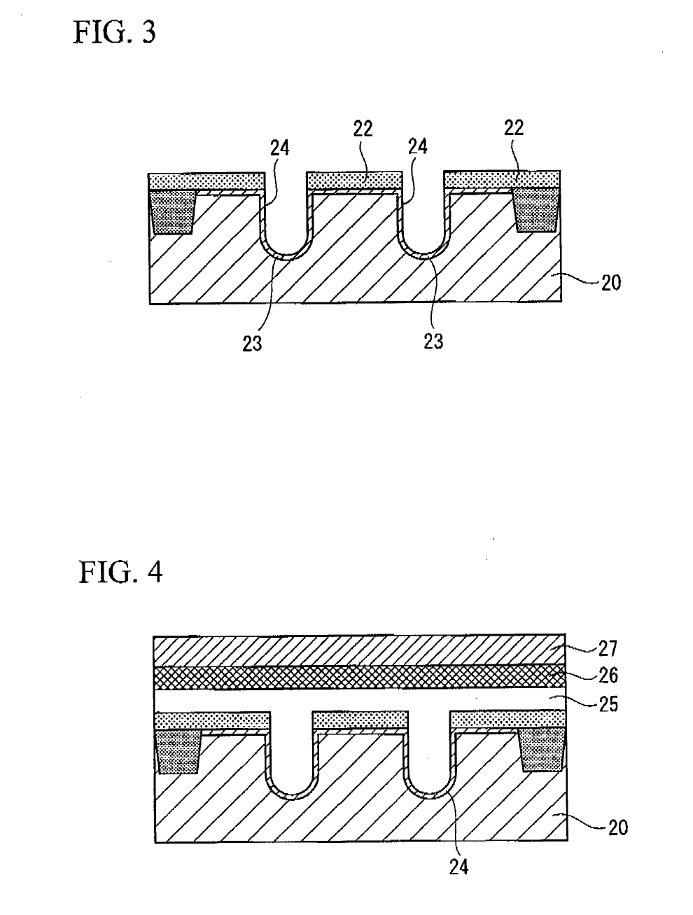

FIG. 1 is a conceptual view showing a section structure of a trench gate type semiconductor device according to a first embodiment of the present invention. FIGS. 2 to 8 are conceptual sectional views for explaining au example of a method of manufacturing the semiconductor device.

In these figures, a semiconductor substrate 1 applied to a semiconductor device H of the present invention is formed of a semiconductor containing impurities of predetermined concentration, for example, silicon.

A trench isolation insulating film (device isolation insulating film) 2 is formed at a portion other tan an active region on the semiconductor substrate 1 by a STI (Shallow Trench Isolation) method to electrically isolate neighboring active regions from each other.

In the structure of this embodiment, as shown by the section structure in FIG. 1, a source 4a, a drain 3 and a source 4b are isolated from each other in an active region partitioned by the trench isolation insulating film 2 in the semiconductor substrate 1, a groove 5 is formed into the semiconductor substrate 1 between the source 4a and the drain 3, and a groove 6 is formed into the semiconductor substrate 1 between the drain 3 and the source 4b.

A gate insulating film 7 is formed in the inner sides of the grooves 5 and 6 and on a substrate surface at opening edges 5A and 6a of the grooves, a lower gate electrode 8 is formed to project upward from the internal of the grooves to contact the gate insulating film 7 in the inner side of the gate insulating film 7 formed in the inner side of the grooves 5 and 6, and an upper gate electrode 9 is formed on the lower gate electrode 8 via misalignment portions 8A and 9A of a step shape. The lower gate electrode 8 and the upper gate electrode 9 compose a gate electrode 10.

In the gate electrode 10 shown in FIG. 1, the upper gate electrode 9 is misaligned to the left with the lower gate electrode 8, and the misalignment portion 9A is disposed in the left side and the misalignment portion 8A is disposed in the right side. That is, the misalignment portion 9A is formed at tie bottom of the upper gate electrode 9 as the upper gate electrode 9 is deviated from the lower gate electrode 8 toward the left side of FIG. 1 by one of several of width of the lower gate electrode 8. Similarly, the misalignment portion 8A is formed at the top of the lower gate electrode 8 as the upper gate electrode 9 is deviated from the lower gate electrode 8 toward the left side of FIG. 1 by one of several of width of the lower gate electrode 8.

Such a misalignment may occur due to a positional displacement between a first photolithography and a second photolithography used to form a complete gate electrode in a gate electrode forming process by performing photolithography twice which will be described later. Although it is desirable if there occurs no misalignment, the present invention aims at proper transistor operation even in such misalignment.

The problems to be solved by the present invention can be solved when the structure of this embodiment is employed for various cases including a case where the upper gate electrode 9 shown in FIG. 1 is deviated from the lower gate electrode 8 toward the right side of the figure, or left and right misalignment are different for each region when a plurality of trench gate transistors are formed on the semiconductor substrate 1, a case where the upper gate electrode 9 is deviated from the lower gate electrode 8 when viewed in a direction perpendicular to the section shown in FIG. 1 although the upper gate electrode 9 is not deviated from the lower gate electrode 8 when viewed from the section shown in FIG. 1, etc, depending on conditions of photolithography. Of course, when a plurality of trench gate transistors are formed on the semiconductor substrate 1, the structure of this embodiment can be effective for a case where some of the trench gate transistors are misaligned as shown in FIG. 1 but the other of the trench gate transistors are not misaligned, that is, for a semiconductor devices including both of misaligned trench gate transistors and aligned trench gate transistors.

A conductor (a portion also used as a portion of a word line in a DRAM structure) 11 and a mask layer (insulating film hard mask) 12 are laminated on the upper gate electrode 9, and a coating insulating film 13 is formed to cover the upper side of the upper gate electrode 9 project upward from the semiconductor substrate 1, a portion of the conductor 11 located thereon, and both sides and top of the mask layer 12 located thereon.

Since the top of the lower gate electrode 8 is formed at a position higher than the gate insulating film 7 formed in the opening edges 5A and 6A of the grooves 5 and 6, a space between the misalignment portion 9A and the semiconductor substrate 1 is larger than the thickness of the gate insulating film 7.

In the example of FIG. 1, a distance between the misalignment portion 9A and the semiconductor substrate 1 is several times as large as the thickness of the gate insulating film 7. For example, if the thickness of the gate insulating film 7 is 3 to 10 nm, a distance between the misalignment portion 9A and the top of the gate insulating film 7 is 10 to 20 nm. In this case, a width of the gate electrode 8 is, for example, 70 to 100 nm.

In the section structure shown in FIG. 1, the width of the lower gate electrode 8 is equal to the width of the upper gate electrode 9, and a portion of the conductor 11 and a portion of the mask layer 12 which are surrounded by the coating insulating film 13 in the top of the upper gate electrode 9 have the same width as the upper gate electrode 8.

In addition to the above-described configuration, although shown in a simplified form in FIG. 1, the semiconductor device H having the trench gate transistor of this embodiment includes a source electrode 15 extending to the source 4a through the upper gate insulating film 9 of the source 4a, a drain electrode 16 extending to the drain 3 through the upper gate insulating film 9 of the drain 3, and a source electrode 17 extending to the source 4b through the upper gate insulating film 9 of the source 4b.

In the structure of this embodiment, one trench gate transistor is composed of the gate insulating film 7 and the gate electrode 10, which are formed in the groove 5, and the source 4a, the drain 3, the source electrode 15, and the drain electrodes 16, which are disposed at both sides of the gate insulating film 7 and the gate electrode 10, and another trench gate transistor is composed of the gate insulating film 7 and the gate electrode 10, which are formed in the groove 6, and the drain 3, the source 4b, the drain electrode 16, and the source electrode 17, which are disposed at both sides of the gate insulating film 7 and the gate electrode 10.

In the semiconductor device H of this embodiment, even when the upper gate electrode 9 is laminated on the lower gate electrode 8 in misalignment since the distance between the misalignment portion 9A and the source 4a or the drain 3 is larger than the thickness of the gate insulating film 7, the distance between the misalignment portion 9A and the source 4a or the drain 3 can be sufficiently secured, thereby avoiding a problem of increasing parasitic capacitances as compared to the above-described conventional structure shown in FIG. 18 where the misalignment portion 105D is fight on the gate insulating film 9, thereby increasing the parasitic capacitance.

In addition, in the conventional structure shown in FIG. 18, since a convex portion of the misalignment portion 105D is right on the gate insulating film 9 and is adjacent to the source and the drain, and accordingly, an electric field is likely to be concentrated on the misalignment portion 105D, there may occur the problems related to GIDL withstand voltage and reliability of gate insulating film. However, the semiconductor device H of this embodiment, since the distance between the misalignment portion 9A and the source 4a or the drain 3 is larger than the thickness of the gate insulating film 7, here occurs no problem of deterioration of GIDL withstand voltage and reliability of gate insulating film due to the misalignment.

Next, an example of a method of manufacturing the semiconductor device having the trench gate transistor structure of the present invention will be described in a process order with reference to FIGS. 2 to 8.

As shown in FIG. 2, a trench isolation insulating film (device isolation insulating film) 21 is formed on a silicon substrate 20 by a STI method. In this process, active regions are isolated from each other. Next, a buffer insulating film 22 such as a SiO₂ insulating film is formed at thickness of 10 to 20 nm on the semiconductor substrate. The buffer insulating film 22 is required to be formed thicker than a gate insulating film to be later formed on the silicon substrate 20.

Next, using a resist mask to pattern a groove by a photolithography method, a groove 23 is formed at a depth of 100 to 150 nm by a dry etching method, and then a gate insulating film 24 is formed by a thermal oxidation method. Here, the surface of the silicon substrate 20 covered by the buffer insulating film 22 is not nearly oxidized or slightly oxidized. For example, if the gate insulating film is formed at thickness of 5 to 10 nm by thermal oxidation in the internal of the groove 23, the silicon substrate 20 below the buffer insulation film 22 is oxidized to a level of 0 to 1 nm.

Next, an electrode film 25 for gate electrode made of ion-doped polysilicon is formed at thickness of 50 to 100 nm by a CVD method. Here, if gate electrodes of different N type and P type are formed, non-doped polysilicon may be deposited instead of the ion-doped polysilicon, and then a gate dopant may be injected. When the electrode film 25 is formed at thickness of 50 to 100 nm, the internal of the groove 23 is completely filled with the electrode film 25, and the electrode film 25 is deposited on the buffer insulating film 22.

In addition, a laminated film 26 having a three-layered (W/WN/WSi) structure is formed by laminating a tungsten silicide (WSi) layer of thickness of 5 to 10 nm on the electrode film 25 by a CVD method, laminating a WN nitride layer of thickness of 10 nm or so thereon by a sputtering method, and laminating a W metal electrode layer of thickness of 55 nm or so thereon by a CVD method, and subsequently, a SiNx mask layer (mask insulating film) 27 of thickness of 140 nm or so is laminated on the laminated film 26 by a CVD method.

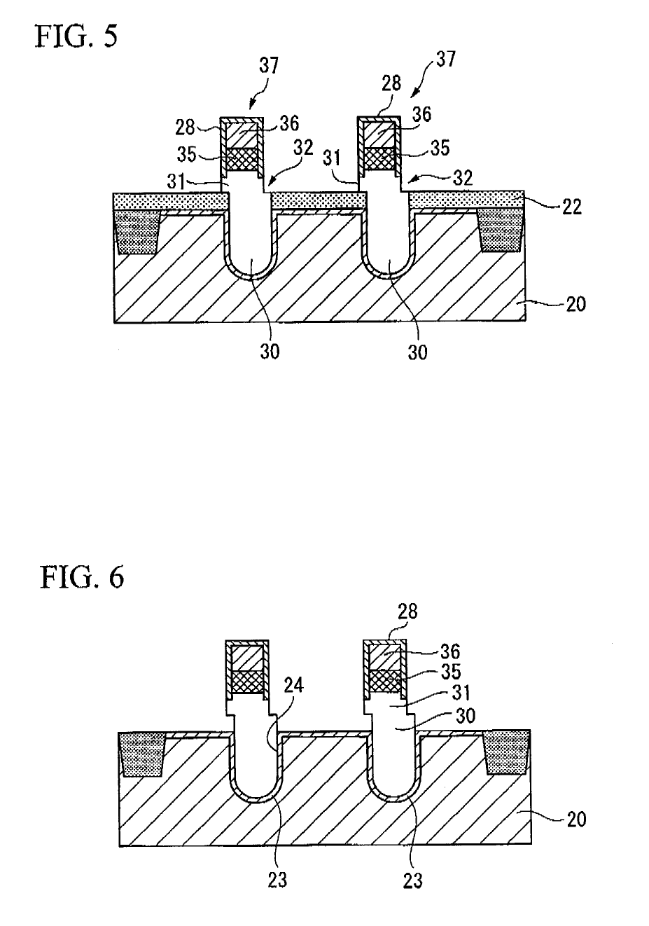

A corresponding portion of the mask layer 27 to be the gate electrode is patterned by a photolithography method, the mask layer 27, the laminated film 26, and the upper portion of the gate electrode layer 25 are etched by a dry etching method using the patterned portion, a WSi coating insulating film 28 is formed, the remainder of the gate electrode 25 is etched. As a result, as shown in FIG. 5, a gate electrode 32 including a lower gate electrode 30 and an upper gate electrode 31, and a laminate 37 including a conductor (word line) 35, a mask layer 36 and a coating insulating film 28 covering the conductor 35 and the mask layer 36 are formed on the buffer insulting film 22.

Thereafter, the buffer insulating film 22 is removed using a HF chemical solution, as shown in FIG. 6.

Subsequently, N-type impurities (for an NMOS region) or P-type impurities (for a PMOS region) are injected using tilted ion implantation to form the sources 4a and 4b or the drain 3.

If necessary, side walls are formed on both sides of the gate electrode 32, and then ions are injected therein to a source/drain structure. If a level of misalignment is low, ions may be injected using vertical ion implantation instead of the tilted ion implantation.

With the structure obtained so, a SiO₂ interlayer insulating film 40 is formed to cover the gate electrode 32, a contact hole reaching the gate insulating film 24 right on the sources 4a and 4b or the drain 3 is formed, conductive contact plugs 41 (source electrode), 42 (source electrode) and 43 (drain electrode) are formed to reach the sources 4a and 4b or the drain 3, metal wires 45, 46 and 47 are formed, and a SiO₂ protection film 48 is formed, thereby obtaining a semiconductor device H′ as shown in FIG. 8.

The semiconductor device H′ manufactured as described above has the same basic structure, operation and effects as the semiconductor device H as described earlier.

With her progress for this structure a DRAM can be obtained by forming a plurality of trench gate transistors on the silicon substrate and providing required number of capacitor structures on metal wires.

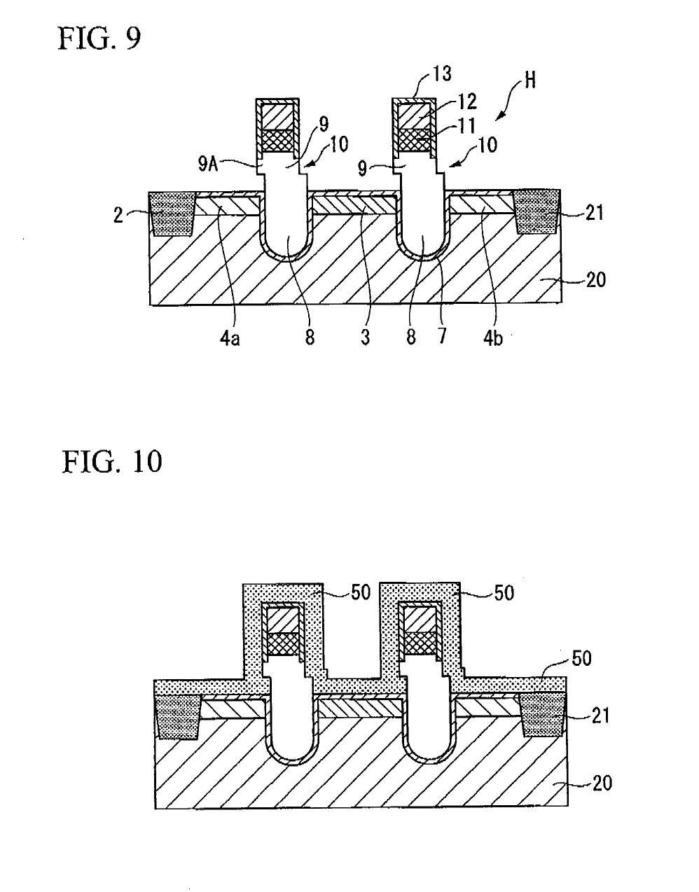

Although the method of forming the contact plugs 41, 42 and 43 are shown in a simplified form in FIG. 8, an example of forming the contact plugs by a SAC (Self Align Contact) method will be hereinafter described with reference to FIGS. 9 to 14.

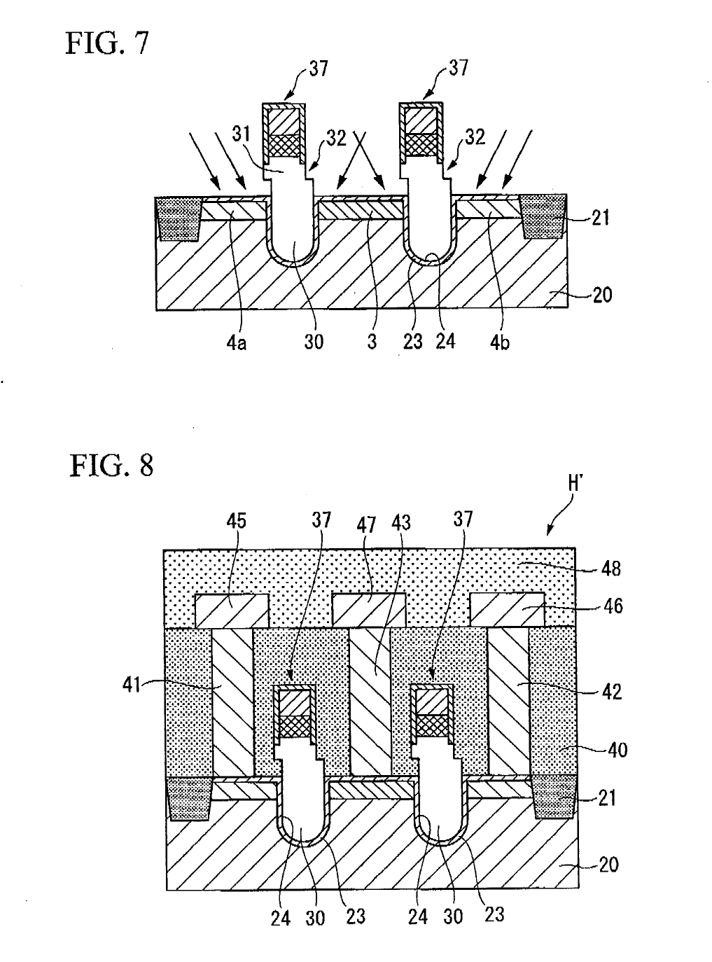

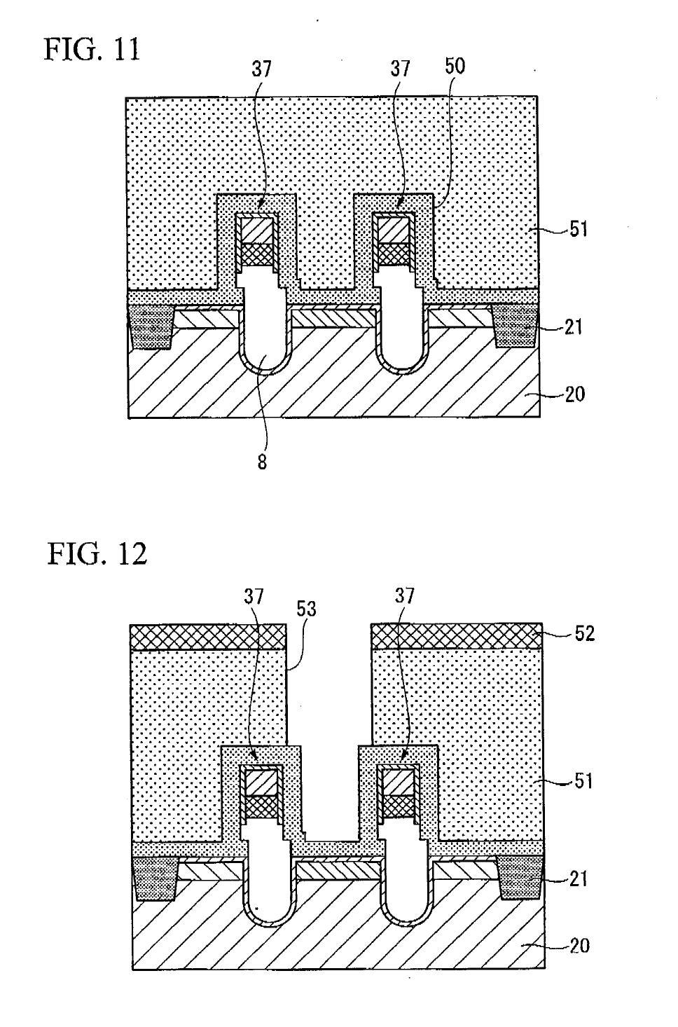

With the same transistor structure as that of FIG. 7 as shown in FIG. 9, a SiNx gate side wall protection film 50 is coated at thickness of 5 to 20 nm as shown in FIG. 10, and subsequently, a SiO₂ interlayer insulating film 51 is coated at thickness of 500 to 700 nm to cover an entire gate electrode laminate as shown FIG. 11.

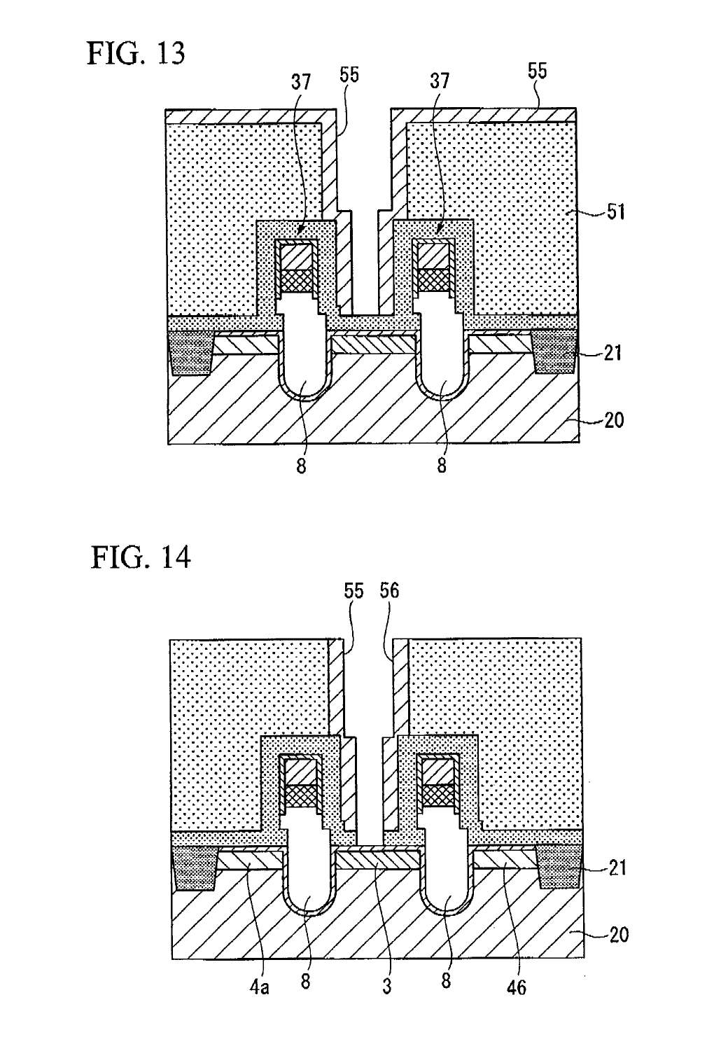

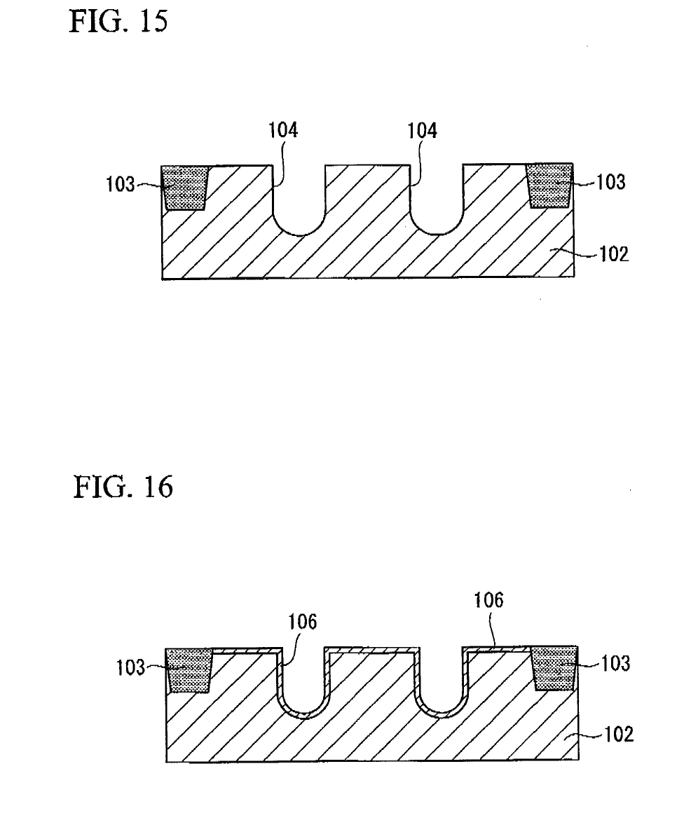

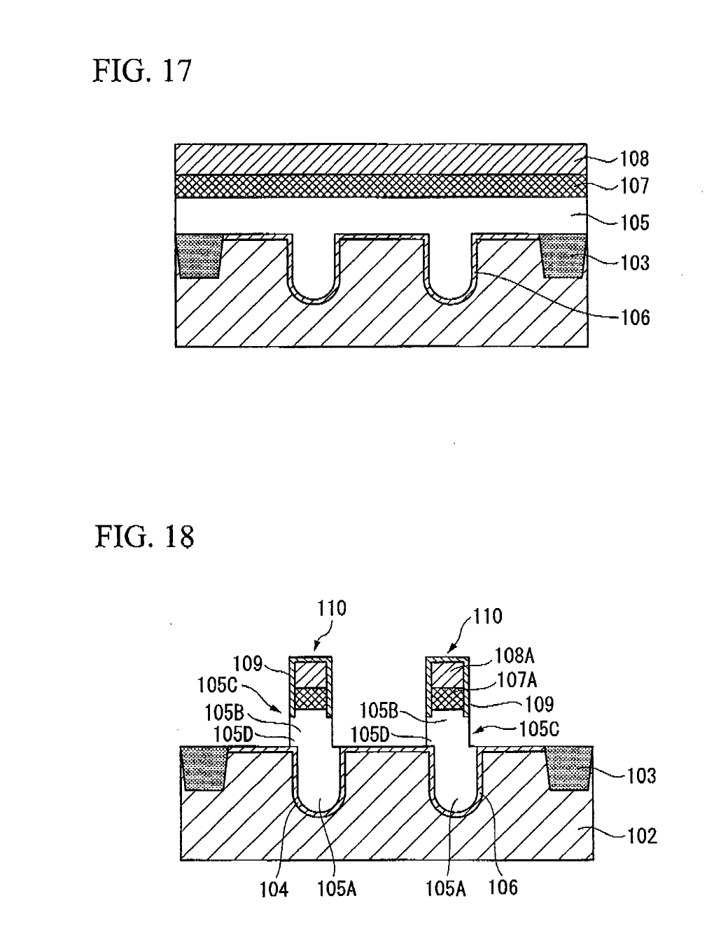

Next a resist layer 52 is coated on the interlayer insulating film 51, patterned and etched to form a contact hole 53 reaching a portion between laminates 37 and 37, and then a SiNx side wall film 55 is formed in the inner side of the contact hole 53 and on the top of the interlayer insulating film 51, as shown in FIG. 13. Subsequently, the gate insulating film 24 at the bottom of the side wall film 55 and a contact hole 56 on the interlayer insulating film 51 is removed to form the contact hole 56 surrounded by the side wall film 55, as shown FIG. 14, and the internal of the contact hole 56 is filled with a conductive material to form the contact plug (drain electrode) like the contact plugs 41, 42 and 43 as shown in FIG. 8.

FIGS. 9 to 14 show one contact plug connected to the drain 3 in a simplified formed, but in actuality, contact plugs have to be also formed at the sources 4a and 4b. In this case, in addition to the contact hole 53 formed in the resist layer 52 shown in FIG. 12, separate contact layers are also formed on the top of the sources 4a and 4b, and the processes shown in FIGS. 13 and 14 may be performed for the separate contact holes.

Through these processes, the contact plugs respectively connected to the sources 4a and 4b and the drain 3 can be formed to obtain the semiconductor device having the same structure as that shown in FIG. 8.

The semiconductor device as manufactured above can obtain effects of reduction of parasitic capacitance, enhancement of GIDL withstand voltage like the semiconductor device described earlier with reference to FIG. 8.

While preferred embodiments of the present invention have been described and illustrated above, it should be understood that these are exemplary of the present invention and are not to be considered as limiting. Additions, omissions, substitutions, and other modifications can be made without departing from the spirit or scope of the present invention. Accordingly, the present invention is not to be considered as being limited by the foregoing description, and is only limited by the scope of the appended claims.

What is claimed is:

1. A semiconductor device comprising a trench gate transistor including a groove formed on a semiconductor, a gate electrode formed in the groove via a gate insulating film, and a source and a drain disposed near the gate electrode on the semiconductor substrate via the gate insulating film,
wherein: the gate electrode extends from an inner side of the groove to an outer side of the groove;
the gate electrode has a misalignment portion in a width direction from the inner side of the groove to the outer side of the groove;
the misalignment portion of the gate electrode is formed at a side higher than an opening edge of the groove; and
a height from the opening edge of the groove to the misalignment portion is larger than a thickness of the gate insulting film.

2. The semiconductor device according to claim 1, wherein a portion from a side wall of the gate electrode located at the opening edge of the groove formed on the semiconductor substrate to the misalignment portion of the gate electrode is surrounded by an interlayer insulating film laminated on the semiconductor substrate.

3. The semiconductor device according to claim 1, wherein: the gate electrode is divided into a lower gate electrode and an upper gate electrode by the misalignment portion; and
the top of the lower gate electrode extends upper than the opening edge of the groove and the gate electrode around the opening edge.

4. The semiconductor device according to claim 1, wherein: a conductor and a mask insulating film are formed on the upper gate electrode to extend the gate electrode; and
the semiconductor device further comprises a coating insulating film covering the mask insulating film, the conductor and the upper gate electrode.

5. The semiconductor device according to claim 2, wherein a source electrode and a drain electrode are respectively formed in the source and the drain provided through the interlayer insulating film and the gate insulating film.

6. A method of manufacturing a semiconductor device, comprising the steps of:
forming a device isolation insulating film on a semiconductor substrate;
laminating a buffer insulating film on the semiconductor substrate on which the device isolation insulating film is formed;
forming a groove reaching the semiconductor substrate through the buffer insulating film;
forming a gate insulating film by oxidizing the groove and the semiconductor substrate around the groove by an oxidation method;
forming an electrode film on the semiconductor substrate on which the buffer insulating film and the groove are formed, such that the electrode film fills up the internal of the groove and is deposited over the internal of the groove;
forming a conductive film and a mask layer on the electrode film;
patterning the mask layer;
forming au gate electrode having a misalignment portion in a width direction from an inner side of the groove to an outer side of the groove by machining the conductive film and the electrode film via the mask layer; and
forming a source and a drain on the semiconductor adjacent to the gate electrode by ion implantation.

7. The method of manufacturing a semiconductor device, according to claim 6, further comprising the steps of:
after for the gate electrode having the misalignment portion, exposing the gate insulating film around the gate electrode by removing the buffer insulating film on the semiconductor substrate; and
after exposing the gate insulating film forming the source and the drain on the semiconductor substrate adjacent to the gate electrode by the ion implantation.

8. The method of manufacturing a semiconductor device, according to claim 7, further comprising the steps of:
after forming the source and the drain, forming an interlayer insulating film to surround the gate electrode, the conductive film and the mask layer; and
forming a source electrode and a drain electrode connecting to the source and the drain, respectively, through the interlayer insulating film.
